(19) United States
(12) Patent Application Publication
(10) Pub. No.: US 2026/0215196 A1
(43) Pub. Date: Jul. 23, 2026

(54) SUBSTRATE COMPRISING TRENCHES AND ASSOCIATED MANUFACTURING METHODS

(71) Applicant: COMMISSARIAT A L'ENERGIE ATOMIQUE ET AUX ENERGIES ALTERNATIVES, Paris (FR)

(72) Inventors: Perceval COUDRAIN, Grenoble cedex 09 (FR); Jean CHARBONNIER, Grenoble cedex 09 (FR); Thierry SALVETAT, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/140,837

(22) PCT Filed: Dec. 21, 2023
(86) PCT No.: PCT/EP2023/087266

§ 371 Date: Jun. 18, 2025

(30) Foreign Application Priority Data
Dec. 21, 2022 (FR) FR2214048

(51) Int. Cl. H10P 58/00; H10P 90/00; H10W 10/00; H10W 10/10; H10W 10/20

(52) U.S. Cl. CPC H10P 58/20; H10P 90/1916; H10W 10/061; H10W 10/181; H10W 10/021; H10W 10/20

(57) ABSTRACT

A substrate includes a first layer based upon a semiconductor material and having a front face and a rear face, and an assembly of at least one layer surmounting the first layer by the first face and having a plurality of individual zones for forming microelectronic components. The substrate also includes a plurality of hollow trenches extending, along a thickness dimension of the substrate, at least over one portion of the first layer going up to the front face of the first layer, the trenches being delimited at least by a side wall and a bottom wall buried in the first layer, the trenches forming a closed contour around at least one individual zone.

### TECHNICAL FIELD OF THE INVENTION

The present invention relates to the field of substrates intended to manufacture electronic devices, and more specifically, microelectronic devices, these substrates ultimately making possible to more effectively produce component-based devices produced collectively. The invention advantageously applies, but in a non-limiting manner, to manufacturing microelectronic devices.

### PRIOR ART

The collective production of microelectronic devices, and in particular, of dies, is a very common practice, and is performed on the base of a substrate. This comprises zones, each dedicated to the formation of a device, the latter comprising one or more components formed in such a zone. The substrates used for collective manufacture can, in particular, be semiconductor substrates, for example, of the semiconductor-on-insulator type, and in particular, silicon-on-insulator SOI (English short for Silicon-On-Insulator).

After the production of components from different devices on the substrate, the devices are singled out, i.e. that the substrate is divided into as many parts as final devices to be obtained. This singling out occurs at the very end of the component manufacturing cycle, and in particular, after the deposition of the metal layers of the back-end-of-line (abbreviated BEOL, which translates as back-end-of-line).

The cutting of the substrate involved by the singling out, has numerous disadvantages. First, it has proved to be generally time-consuming, insofar as the substrate must be cut successively along different directions. And, according to the techniques used, for example, when cutting plasmas are resorted to, several passes can be necessary. In addition, the cutting can degrade the surface quality of microelectronic devices, and the size of the cuts is generally several tens of micrometres wide, which consumes a significant surface of the substrate.

There is currently a need to obtain individualised microelectronic devices, in an improved manner, in a collective manufacturing context on a substrate.

An aim of the present invention is therefore to facilitate the manufacture of microelectronic devices from a substrate.

The other aims, features and advantages of the present invention will appear upon examining the description below and the accompanying drawings. It is understood that other advantages can be incorporated.

### SUMMARY OF THE INVENTION

To achieve this aim, according to an embodiment, a substrate is provided, comprising:
a first layer with the basis of a semiconductor material and comprising a front face and a rear face,
an assembly of at least one layer, surmounting the first layer by the front face, and comprising a plurality of individual zones for forming microelectronic components.

Advantageously, the substrate comprises a plurality of hollow trenches, extending along a thickness dimension of the substrate, at least one portion of the first layer going up to the front face of the first layer, the trenches being delimited at least by a side wall and a bottom wall buried in the first layer, the trenches forming a closed contour around at least one individual zone.

Thus, the substrate comprises trenches, preferably manufactured before the manufacture of the components forming the microelectronic devices.

This has several advantages. The singling out of the microelectronic devices is prepared before the manufacture of the latter. This avoids the negative impact that current end-of-process singling out methods have, in particular, by removing any risk of degradation of the devices. On the other hand, the trenches can be produced simultaneously with etching techniques, which is a lot less time-consuming than currently known die cutting.

Generally, the substrate, in this case, focuses on carrying microelectronic components during different steps of their manufacture. After the manufacture of the components, the substrate is divided into as many parts as microelectronic devices to be formed from the components. However, thanks to the invention, this division is facilitated by the structure of the substrate. Indeed, trenches are formed beforehand, such that, when the substrate is used to manufacture the components, they are already in place. At the end of the method, the trenches are used as zones for dividing the microelectronic devices. While the phase of singling out devices is usually perceived as a step fully subsequent to the manufacture of the components on the substrate, the present substrate structure fights this prejudice, by anticipating this singling out by a manufacture of the trenches upstream of that of the components.

Also, the size of the trenches is potentially very narrow, even though the space occupied by this singling out part can be broadly decreased, compared with the current techniques.

According to an example, at least the bottom wall and the side wall are made of dielectric material. The dielectric material walls being formed beforehand, they enable a good insulation and/or passivation of the trenches, and can, in particular, be implemented by high-temperature methods (in particular, thermal oxidation annealing) without impact on the components which are not yet formed.

A second aspect relates to a method for manufacturing the substrate according to the first aspect, comprising:
a provision of a support sub-substrate comprising at least one first layer with the basis of a semiconductor material, the support sub-substrate having an exposed surface,
an etching of a plurality of trenches, such that the trenches extend along a thickness dimension of the substrate from the exposed surface over a portion of the first layer, each trench being delimited by a side wall and a bottom wall buried in the first layer, the trenches forming a closed contour around at least one individual zone for forming microelectronic components,
a provision of a donor sub-substrate comprising a superficial layer having an exposed surface,
an assembly of the support sub-substrate and of the donor sub-substrate by their exposed surfaces, so as to cover the trenches, each trench thus being delimited by the side wall, the bottom wall, and an upper wall opposite the bottom wall.

This method thus enables the manufacture of the substrate which can then be used to obtain the microelectronic devices, by individualising them. This method has the effects and advantages described relative to the first aspect.

A third aspect relates to a method for manufacturing a microelectronic device, comprising:
a provision of a substrate having a front exposed surface and a rear exposed surface,
a tapering of the first layer from the rear face, up to opening the trenches.

This method advantageously ultimately makes it possible to separate the microelectronic devices. By this tapering or at least partially thanks to it, the method makes it possible to individualise each device.

### BRIEF DESCRIPTION OF THE FIGURES

The aims, objectives, as well as the features and advantages of the invention will best emerge from the detailed description of embodiments of the latter, illustrated by the following accompanying drawings.

FIG. 1A represents a cross-sectional view of a substrate carrying a plurality of components intended to form microelectronic devices according to an embodiment.

FIG. 1B represents a cross-sectional view of a substrate carrying a plurality of components intended to form microelectronic devices according to another embodiment.

FIG. 2 represents a partial view along the cross-section AA of the two preceding figures.

FIG. 3 shows an example of a result for individualising microelectronic devices from a substrate according to FIG. 1B.

FIGS. 4A to 4E represent cross-sectional views of steps of the method for manufacturing the substrate according to examples of embodiments.

FIGS. 5A and 5B have subsequent steps of the method for manufacturing the substrate according to examples of embodiments.

FIGS. 6A to 6E illustrate successive steps going from the manufacture of components on the substrate, up to the transfer of the substrate onto a support.

FIGS. 7A and 7B represent an alternative to the sequence represented between FIGS. 6A and 6B.

The drawings are given as examples and are not limiting of the invention. They constitute principle schematic representations, intended to facilitate the understanding of the invention, and are not necessarily to the scale of practical applications. In particular, the relative dimensions of the sub-substrates and substrates, of the layers, of the trenches and of the walls, are not representative of reality.

### DETAILED DESCRIPTION OF THE INVENTION

Before starting a detailed review of embodiments of the invention, optional features are stated below, which can optionally be used in association or alternatively.

According to the examples, the substrate is such that:
it comprises at least one microelectronic component 40 in the at least one individual zone 331;
complementary trenches 42 extend along the thickness dimension from an exposed face of the component 40 up to the mouth of the trenches 32;
each trench 32 extends into the first layer 30 over at least 10%, and/or preferably over at least 50%, of the thickness dimension of the first layer 30;
the assembly 36 comprises a second layer 31 in contact with the front face of the first layer 30 and which, preferably, is a layer with the basis, and preferably made, of a material chosen from among a dielectric material, for example, an oxide, a semiconductor material or a piezoelectric material;
the assembly 36 comprises a third layer 33 surmounting the second layer 31 and which, preferably, is with the basis of a material chosen from among a semiconductor material or a piezoelectric material;
at least the bottom wall 321 and the side wall 320 are made of dielectric material;
at least the bottom wall 321 and the side wall 320 comprising a layer made of a dielectric material fully covered by a metal coating;
each trench 32 has at least one smallest transverse dimension less than 10 μm;
at least one part of the trenches 32, and preferably each trench 32, has a shape ratio, of the trench 32 dimension along the thickness dimension over the smallest transverse dimension to the thickness dimension, greater than or equal to 10;
the substrate 3 further comprises a system 34 configured so as to enable the alignment of the substrate 3.
According to an example, the trenches are parallel to one another along the thickness dimension of the substrate. Moreover, they can be of the same depth dimension in the substrate.
According to an example, the trenches form a mesh in the substrate, preferably, with two directions of trenches perpendicular to one another. Alternatively, the trenches can have a curved profile, and for example, circular around the individual zones for forming the components.

According to an example, the trenches are not filled with a solid material. Each groove is preferably filled with an electrically insulating gaseous atmosphere, for example, air, nitrogen or argon, optionally at a pressure less than or equal to ambient pressure. This arrangement is advantageous for the resistance of components at subsequent steps with high thermal budgets, typically of at least 1000° C.

According to an example, each trench is delimited by a bottom wall, a side wall and an upper wall opposite the bottom wall. For at least one trench, and preferably for each trench, at least one part of the side wall and of the bottom wall can be made of the same material as that of the first layer. Alternatively, for at least one trench, and preferably for each trench, at least one part of the side wall and of the bottom wall can be made of dielectric material, for example, the same dielectric material as the walls of the trench. Thus, the electrical insulation of the flank of the final microelectronic device is already achieved.

In the case where the substrate further comprises a system configured so as to enable the alignment of the substrate, this makes it possible to further facilitate the manufacture of microelectronic devices, by facilitating the alignment of the substrate, and in particular, for the carrying out of the photolithography steps necessary for the construction of the active zones of the circuits, and of the different conductive lines of the component manufacturing processes. For a CMOS-type manufacturing method, the first brick is the insulation of the active zones of the transistors, it is therefore itself which would be aligned on these marks. According to an example, the semiconductor material is chosen from among the group constituted of silicon Si, germanium Ge, SiGe, a III-V material (for example, GaN, InN, InGaAs, GaP, InP, InAs, AsGa, etc.), a II-VI material, wide bandgap materials, for example, greater than 3 eV.

According to an example, the semiconductor material comprises, and preferably is, silicon. According to an example, the piezoelectric material is chosen from among lithium tantalum (LiTaO₃), lithium niobate (LiNbO₃), potassium-sodium niobate (KₓNa₁₋ₓNbO₃ or KNN), barium titanate (BaTIO₃), quartz, lead zirconate titanate (PZT), a lead-magnesium and lead titanate compound (PMN-PT), zinc oxide (ZnO), aluminium nitride (AIN) or aluminium and scandium nitride (AlScN).

According to an example, the dielectric material is a semiconductor oxide, and preferably silica of chemical formula SiO₂.

According to different options, the method for manufacturing the substrate can comprise the following features cumulatively or alternatively according to any combination:
it comprises a formation of at least one microelectronic component 40 in the at least one individual zone after assembly of the support sub-substrate 1 and of the donor sub-substrate 2.
It comprises, after the formation of at least one microelectronic component 40, a formation of complementary trenches 42 extending along the thickness dimension from an exposed face of the at least one component 40 up to the mouth of the trenches 32;
following the etching of the plurality of trenches 32, and preferably before the assembly of the support sub-substrate 1 and of the donor sub-substrate 2, the method comprises, for each trench 32, a formation of a dielectric material at least the bottom wall 321 and the side wall 320;
the formation of a dielectric material at at least the bottom wall 321 and the side wall 320 of the plurality of trenches 32 comprises:
   a thermal oxidation, so as to oxidise the semiconductor material of the first layer 10 at at least the bottom wall 321 and the side wall 320, and/or
   a deposition of the dielectric material at at least the bottom wall 321 and the side wall 320.
The superficial layer 21 of the donor sub-substrate is a layer with the basis, and preferably made, of a material chosen from among a dielectric material, for example, an oxide, a semiconductor material or a piezoelectric material;
the support sub-substrate 1 further comprises a superficial layer 11 with the basis, and preferably made, of a dielectric material, for example, an oxide, surmounting the first layer 10, the superficial layer having the exposed surface 1a, and/or the superficial layer 21 of the donor sub-substrate is a layer with the basis, and preferably made, of a dielectric material, for example, an oxide, surmounting a layer 20 with the basis of a material chosen from among a semiconductor material or a piezoelectric material.
After the assembly of the support sub-substrate 1 and of the donor sub-substrate 2, a tapering of the donor sub-substrate 2 is configured to expose the superficial layer 20, 21.
a provision of a substrate 3 having a front exposed surface 3a and a rear exposed surface 3b,
a tapering of the first layer 30 from the rear face 3b up to opening the trenches 32.

According to an example, when at least the bottom wall and the side wall are made of dielectric material, the bottom wall of the plurality of trenches has a longitudinal dimension substantially of between 50 nm and 600 nm, preferably substantially equal to 400 nm.

According to an example, when at least the bottom wall and the side wall are made of dielectric material, the side wall of the plurality of trenches has a transverse dimension substantially of between 50 nm and 600 nm, preferably substantially equal to 400 nm.

According to an example, the superficial layer of the donor sub-substrate is a layer with the basis, and preferably made, of a material chosen from among a dielectric material, for example, an oxide, a semiconductor material or a piezoelectric material.

By the phase of assembling the donor sub-substrate and of the receiver sub-substrate, it is understood that the buried oxide layer of the substrate can come from the donor sub-substrate and/or the support sub-substrate.

According to an option, the substrate comprises at least one hollow additional trench extending, along a thickness dimension of the substrate 3, at least over one portion of the first layer 30 going up to the front face 3a of the first layer 30, the additional trench being delimited at least by a side wall and a bottom wall buried in the first layer 30, the additional trench forming a closed contour in an individual zone 331. These trenches can be formed similarly, and in particular, by etching, and in the same step as the formation of the trenches 32. They can have the same dimension along the thickness of the substrate 3. They enable an internal cutting in the zone of the component 4, useful, in particular, if this is hollow. The available surface at the centre can, in particular, be used, to place another microelectronic device there.

According to an example, the method comprises a formation of an embrittlement zone at a depth of the surface of the superficial layer of the donor substrate, then a separation of the donor substrate at the embrittlement zone.

According to different options, the method for manufacturing microelectronic devices from the substrate can comprise the following features cumulatively or alternatively according to any combination:
prior to the tapering, a transfer of the substrate 3 onto a support 41 from the face opposite the rear face 3b is comprised; the support 41 can be a semiconductor-based substrate or a support layer, in particular, made of polymer, potentially with an adhesive surface for this transfer;
after the tapering, a formation of a metal coating 35 covering at least the upper wall 322 and the side wall 320 of the trenches 32 is comprised.

By “microelectronic device”, this means any type of device produced with microelectronic means. These devices include, in particular, in addition to devices with a purely electronic purpose, micromechanical or electromechanical devices, as well as optical or optoelectronic devices. This can be a device intended to ensure an electronic, optical, mechanical function, etc. This can also be an intermediate product, only intended for the production of another microelectronic device. This can also be a passive electrical interconnection structure.

It is specified that, in the scope of the present invention, the term “on” or “above” does not compulsorily mean “in contact with”. Thus, for example, the deposition of a layer on another layer, does not compulsorily mean that the two layers are directly in contact with one another, but this means that one of the layers covers the other layer at least partially, by being either directly in contact with it, or by being separated from it by a film, even another layer or another element.

A layer can moreover be composed of several sublayers of one same material or of different materials.

By an element “with the basis” of a material A, this means an element comprising this material A only or this material A and optionally other materials.

In the detailed description below, use can be made of terms such as “longitudinal”, “transverse”. These terms must be interpreted relative to the substrate or to the thickness dimension of the devices. Thus, a longitudinal dimension, a height, a depth or a thickness of an element or of a layer means a dimension along the thickness of the substrate which carries it or which contains it. A width, or also a cross-section or a transverse dimension means a dimension perpendicular to the thickness of the substrate.

Certain parts of the substrate or of the device of the invention can have an electrical function. Some are used for electrical conduction properties and by “electrically conductive” or equivalent, this means elements formed of at least one material having a sufficient conductivity, in the application, to perform the desired function. Other parts, on the contrary, are used for electrical insulation properties and all materials having a sufficient resistivity to achieve this insulation are concerned, and are, in particular, called dielectric or electrically insulating.

The word “dielectric” qualifies, more specifically, a material, the electrical conductivity of which is sufficiently low in the given application to be used as an insulator. In the present invention, a dielectric material preferably has a dielectric constant less than 4.

By “direct bonding”, this means a bonding without intake of adhesive material (of the glue or polymer type, in particular) which consists of the contacting of relatively smooth surfaces (of a root mean square RMS, from English Root Mean Square, typically less than 5 Å, 10⁻¹⁰m), for example, achieved at ambient temperature, and under an ambient atmosphere, in order to create an adherence between them.

According to an embodiment, the direct bonding of two substrates means that the bonding is obtained by chemical bonds which are established between the two surfaces brought into contact. These chemical bonds can, for example, be Van der Waals bonds and/or strong, covalent chemical bonds, in particular, when the bonding is plasma activation-enhanced or followed by a reinforcing heat treatment (typically 200° C. to 1200° C. for one hour).

The direct bonding can be obtained without requiring the application of a significant pressure on the structure to be assembled. A slight pressure can simply be applied to initiate the bonding. A thermal annealing can further be performed to reinforce the bonding.

By a parameter “substantially equal to/greater than/less than” a given value, this means that this parameter is equal to/greater than/less than the given value, plus or minus 10%, even plus or minus 5%, of this value.

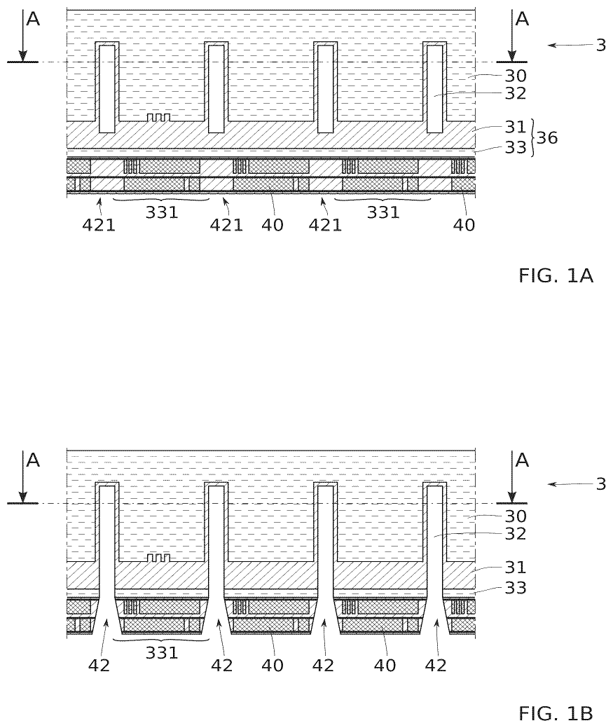

The substrate 3 is now described according to several examples of embodiments in reference to FIGS. 1A and 1B.

As, for example, illustrated by FIG. 1A, the substrate 3 comprises a first layer 30, with the basis or made of a semiconductor material. According to an example, the semiconductor material comprises, and preferably, is silicon. The first layer 30 has a thickness, for example, substantially of between 100 μm and 800 μm.

The substrate 3 further comprises an assembly 36 having at least one layer. FIG. 1A gives a purely indicative example of this assembly. It comprises, in this embodiment, a second layer 31 and a third layer 33. However, the assembly 36 can comprise more than two layers, or also one from among the second layer and the third layer can comprise several sublayers. Conversely, the assembly can only have one layer of one single material; typically, this single layer can be made of semiconductor (and not dielectric) material, such as silicon. It can be used to form a bonding interface during a later exposed transfer phase, in particular, by plasma activation. At the same time, by its other side, this single layer comprises the individual zones for the components 40; this single layer can be produced and used such as described for the third layer 33, but without resorting to the second layer 32.

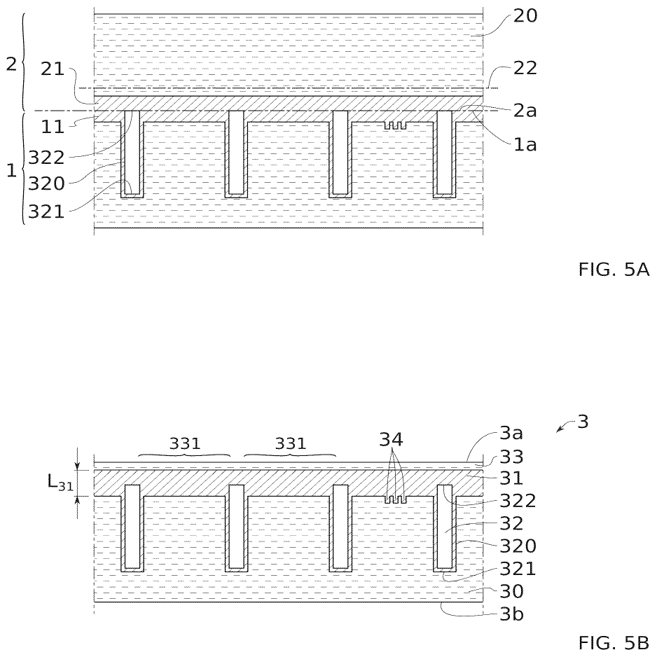

As illustrated by FIG. 1A, the second layer 31 can be with the basis or made of a dielectric material. According to an example, the dielectric material comprises, and preferably, is a semiconductor oxide, for example, silica of formula SiO₂. The second layer 31 forms a stack with the first layer 30, preferably by being directly in contact with it. The second layer 31 can be with the basis or made of a semiconductor material, a piezoelectric material or a metal. The second layer 31 can have a thickness L31, such as noted in FIG. 5B, for example, greater than or equal to 10 nm, preferably 100 nm. The thickness L31 can be less than or equal to 1000 nm. The second layer 31 preferably covers all of the surface of the first layer 30 located inside the closed contours defined by the trenches 32. The second layer 31 preferably covers the trenches 32. The second layer 31 thus preferably fully covers the first layer 30. The second layer 31 preferably fully covers the substrate 3.

The second layer 31 preferably does not comprise any components. This is preferably a layer constituted of one single material (optionally an alloy).

According to an example, as illustrated in FIG. 1A, the second layer 31 is followed by a third layer 33 with the basis or made of a semiconductor material or of a piezoelectric material. According to an example, the semiconductor material comprises, and preferably, is silicon. The third layer 33 has a thickness, for example, substantially of between 10 nm and 1000 nm. The substrate 3 thus comprises a semiconductor-on-insulator-type structure, and in particular, of the silicon-on-insulator (SOI) type. The third layer 33 preferably covers all of the surface of the first layer 30 located inside the closed contours defined by the trenches 32. The third layer 33 preferably fully covers the second layer 31. Preferably, it also covers the trenches 32. The third layer 33 preferably fully covers the substrate 3. It is noted that it can be provided that the second layer 31 is not surmounted by a third semiconductor layer.

Below, unless explicitly mentioned on the contrary, it is considered, in a non-limiting manner, that the substrate 3 is an SOI substrate, the first layer 30 being made of monocrystalline or polycrystalline silicon, the second SiO₂ layer and the third monocrystalline silicon layer.

The substrate 3 comprises hollow trenches 32 extending from the second layer 31 into the first layer 30. The trenches 32 can be parallel to one another. The trenches 32 preferably extend over a longitudinal dimension oriented in the direction of the thickness of the first 30 and second 31 layers, which corresponds to the thickness dimension of the substrate 3. The trenches 32 are buried in the substrate 3, i.e. that they do not open out and, at least on one of the exposed surfaces of the substrate, and in particular, the rear face 3b of the substrate 3.

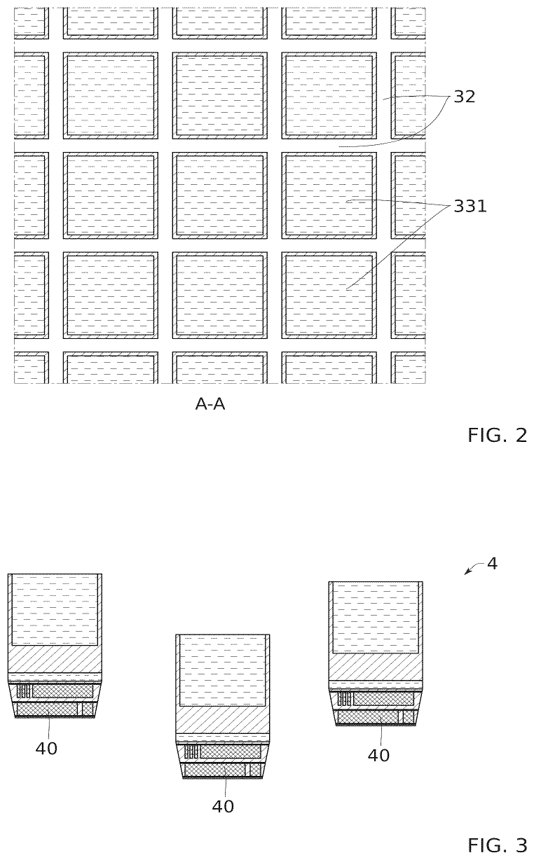

In the case of FIG. 1A, the trenches 32 form closed volumes, insofar as their two ends do not open out and, in particular, by the front face 3a. Indeed, in this case, complementary trenches 42 are formed by the exposed face of the components 40, at the spaces 421 by extending along the thickness dimension of the substrate 3 up to joining the trenches 32. Preferably, the complementary trenches 42 adopt the same distribution as can be seen in FIG. 2 for the trenches 32. In this configuration, for an individual zone 331, the components 40 and the underlying part of the substrate 3 of these components 40 are only integral with the rest of the substrate 3 by a portion of the substrate 3 located opposite the components 40, towards the face 3b of the substrate 3.

With the trenches 32 being hollow, they are not filled with a solid material. They are preferably filled with a gaseous atmosphere, such as air, nitrogen and/or argon, optionally at a pressure less than or equal to ambient pressure.

FIG. 2 provides an example of meshes produced by the trenches 32. In the illustrated case, parallel trenches along a direction of the plane of the substrate are present, as well as parallel trenches along a second direction of this plane, preferably perpendicular to the first. In this configuration, the trenches of the two directions are cut, zones 331 are formed with a closed contour. Preferably, all of the substrate has such a trench composition, forming a sort of grid. This grid can make it possible to produce rectangular-, even square-shaped zones 331. At the very least, the trenches make it possible to frame at least one zone 331 by forming a closed contour around this zone.

Preferably, the trenches are produced simultaneously, by etching as described in more detail below. This enables a limited production time, given this overall manufacture.

Furthermore, the trenches can be rectilinear or not along the contour that is sought to be given to the individual zones 331.

The depth dimension of the trenches 32 can be chosen so as to extend into a portion of the first layer 30 and over at least one portion of the thickness of the second layer 31, as for example illustrated in FIGS. 1A and 1B. In a non-represented variant, the trenches 32 can be flush with the surface of the first layer 30.

The depth dimension of the represented trenches is of at least 10%, possibly at least 20%, even at least 30% of the thickness of the first layer 30. Alternatively, or complementarily, this value can be less than 50%. Indeed, the individualisation of the microelectronic devices which follows is achieved by tapering of the first layer by its rear face, even though it is advantageous to have a significant trench depth, as this is not impeding on the resistance of the substrate 3.

The trenches 32 are delimited by a side wall 320, a bottom wall 321 and an upper wall 322 opposite the bottom wall 321. The bottom wall 321 is disposed towards the rear surface 3b of the substrate 3 and the upper wall 322 is disposed towards the front surface 3a of the substrate 3.

Among these walls, at least the bottom wall 321 and the side wall 320 can be made of dielectric material, for example, SiO₂. Thus, the trench 32 will be electrically insulated from the first layer 30. As FIG. 1A and FIG. 1B illustrate, all the walls of the trenches 32 can be made of dielectric material.

The electrical insulation of the trenches 32 can be done later during the method for manufacturing microelectronic devices from the substrate 3, described below.

The trenches can have a minimum transverse dimension, i.e. a width substantially less than or equal to 10 μm, preferably substantially between 1 μm and 10 μm, even less than 5 μm. Thus, the lateral dimension is low, which makes it possible to occupy little space for the singling out of the microelectronic devices of the substrate 3 in the main extension plane of the first 30 and second 31 layers, which can lead to a greater density of microelectronic devices on a substrate of conventional size. The longitudinal dimension of the trenches can be substantially less than or equal to 200 μm, preferably substantially of between 50 and 150 μm, for example, substantially equal to 100 μm.

The trenches 32 can have a form factor substantially greater than or equal to 5, and preferably greater than or equal to 10. By “form factor”, this means the ratio between the longest dimension (depth along the thickness of the substrate 3) over the shortest dimension (a dimension in the extension plane of the layers 30, 31, 33).

As FIG. 5B illustrates, for example, the substrate 3 can comprise at least one mark or equivalently, a system 34 enabling the alignment of the substrate 3 with other elements. Thus, the placement of the trenches 32 during the method for manufacturing the microelectronic device is made reliable. This system 34 can be formed by one or more layer portion(s) of dielectric material at the first layer 30 and/or the second layer 31. It is noted that a person skilled in the art can absolutely consider other system variants, like for example, a marking disposed on the front surface 3a of the substrate 3.

Steps of the method for manufacturing the substrate 3 are now described in reference to the figures.

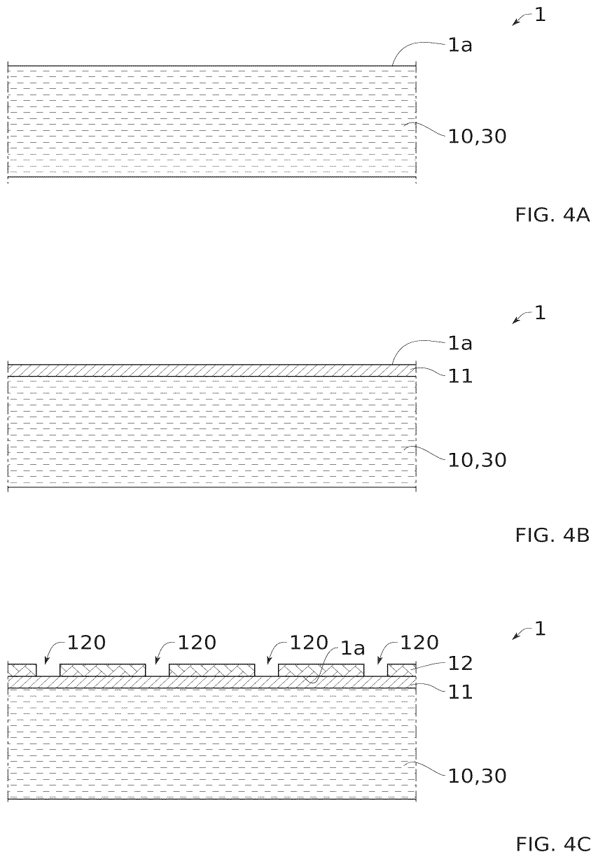

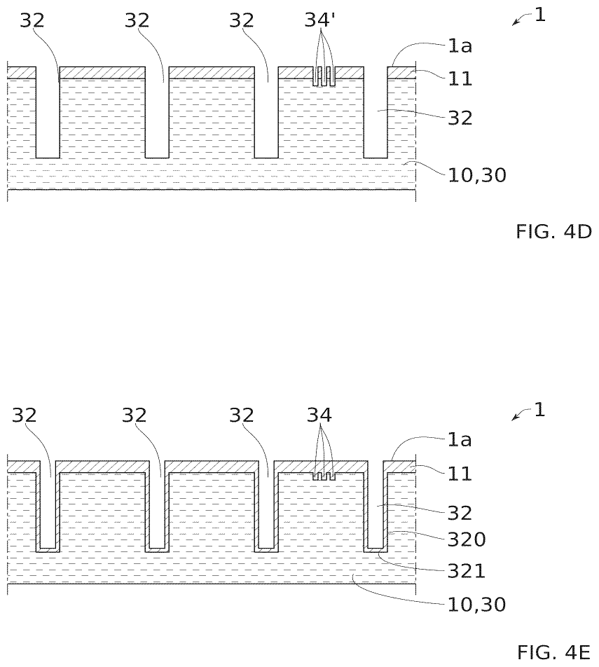

The method comprises the provision of a sub-substrate 1. The sub-substrate 1 comprises at least one first layer 10, intended to form the first layer 30 of the substrate 3 which will be obtained, as FIG. 4A illustrates. The sub-substrate 1 can further comprise, as for example illustrated by FIG. 4A. The sub-substrate 1 can further comprise, as for example illustrated by FIG. 4B, a superficial layer 11 intended to form, at least partially, the second layer 31 of the substrate 3. The superficial layer 11 is preferably with the basis or made of a dielectric material. The sub-substrate 1 further has an exposed surface 1a, at the first layer 10 or the superficial layer 11.

As, for example, illustrated by FIGS. 4C and 4D, the trenches 32 can be formed by etching, and preferably, by deep reactive ion etching (commonly abbreviated DRIE, from English «Deep Reactive Ion Etching»). To form the trenches 32, the etching step can comprise the application of a mask 12 comprising openings 120 from which the trenches 32 will be etched, as for example, FIG. 4C illustrates. The mask 12 is preferably a resin mask. It can be provided that the mask is hard, for example, with the application of a resin mask 12, then the etching of the superficial layer 11, removing this mask and etching the first layer 10 thanks to the so-called “hard” oxide mask thus formed. It is noted that the superficial layer 11 can be removed after the etching of the trenches 32, and the trenches 32 electrically insulated by deposition of a dielectric layer thereafter.

The etching is preferably configured to obtain the features of the trenches 32 described above, and in particular, their dimensions. For example, the dimensions of the mask 12 and/or the etching time and speed are adjusted for that.

To form the trenches 32, the method can then comprise a formation of a dielectric material at at least the bottom wall 321 and the side wall 320, as, for example, FIG. 4E illustrates. This formation can be done by thermal oxidation, for example, at a temperature of substantially 1050° C. in an atmosphere comprising oxygen.

In a variant or complementarily, the dielectric material, for example, silica SiO₂, can be deposited at at least the walls 320, 321 of the trenches 32. This deposition can be a chemical vapour deposition (commonly abbreviated CVD, from English Chemical Vapor Deposition) from gaseous precursors comprising oxygen and silicon, for example, tetraethyl orthosilicate (commonly abbreviated TEOS from English tetraethyl orthosilicate) or silane of chemical formula SiH₄, optionally combined with dioxygen. The deposition is, for example, a sub-atmospheric CVD (commonly abbreviated SACVD, from English sub-atmospheric CVD), or a plasma-enhanced CVD (commonly abbreviated PECVD, from English Plasma-Enhanced CVD.

Preferably, the mask 12 is removed prior to the formation of these dielectric material walls. In the case where the layer 11 has been used as a hard mask, it is preferable to also remove it.

Preferably, the formation of the walls 320, 321 is configured, such that the dielectric material walls 320, 321 have a dimension substantially of between 50 nm and 600 nm, and preferably, substantially equal to 400 nm. For the side wall 320, this dimension is the transverse dimension. For the bottom wall 321, this dimension is the longitudinal dimension. For example, the thermal oxidation time or the deposition time and/or the deposition speed can be adjusted for that.

The method can comprise, simultaneously or together with the etching of the trenches 32, and if necessary, with the formation of the dielectric material walls, a step of forming the system 34. For that, the mask can further comprise openings, not represented in this case, to etch, for example, openings 34′in the second layer 31 until in the first layer 30, illustrated, for example, in FIG. 4D. The openings 34′can be filled with dielectric material during the formation of the walls. The formation of the system 34 can be distinct from these steps, by the application, for example, of a mask specific to this system 34, etching and filling of the openings 34′. If the formation of the system 34 is distinct from these steps, it is advantageously performed before, to be used as a system for the positioning of the trenches 32.

Following the formation of the trenches 32, these cavities can be covered to be buried during the assembly of the sub-substrate 1 with a donor sub-substrate 2. The method can therefore comprise the provision of a donor sub-substrate 2 having an exposed surface 2a.

As illustrated by FIGS. 5A and 5B, the support 1 and donor 2 sub-substrates can be assembled by the contacting by direct bonding of their respective surfaces 1a, 2a. The donor substrate 2 can then be tapered, for example, by cleaving by the method known as Smart-Cut®.

The assembly can, for that, comprise, before the contacting of the surfaces 1a, 2a, the formation of an embrittlement zone 22 at a non-zero depth from the surface 2a of the donor sub-substrate 2. This embrittlement zone 22 is, for example, formed by ion implantation, such as hydrogen and/or helium ions. It is noted that any other technique of forming an embrittlement zone, and in particular, any other technique used in SOI-type stack development methods, can be considered.

Following the assembly of the support sub-substrate 1 and of the donor sub-substrate 2, the method can comprise the separation of a superficial layer of the donor sub-substrate 2, at the embrittlement zone 22, as in the examples illustrated in FIG. 5B. This separation can be done thermally or mechanically, according to steps known by a person skilled in the art.

Following the separation, the obtained surface 3a can be irregular and damaged. A polishing, chemical smoothing, chemical and/or mechanical and/or thermal and/or atom collection-based or monomer-based ion beam curing of the surface 3a can be performed, such that the surface 3a has a crystalline quality and a roughness suitable for other subsequent methods. Any chemical-mechanical polishing (CMP, English short for Chemical Mechanical Polishing) or thermal method intended to smooth a semiconductor-, and in particular, silicon-based surface, can be considered.

According to an example, the donor sub-substrate 2 comprises a layer 20 with the basis or made of a semiconductor material, for example, made of silicon, and more specifically, made of monocrystalline silicon. The donor sub-substrate 2 can further comprise a layer 21 with the basis or made of a dielectric material, for example, made of silica SiO₂.

According to an example being able to be illustrated by FIGS. 5A and 5B, the layer 21 can form the superficial layer of the donor sub-substrate 2. In particular, a semiconductor oxide direct bonding can be performed, for example, silicon oxide, against semiconductor oxide, for example, silicon oxide. Following their assembly, the layer 21 and the layer 11 will form the second layer 31 of the substrate 3. Their respective thicknesses can therefore be chosen to obtain the desired thickness L31. According to this example, it is understood that the upper wall 322 of the trenches 32 and, if necessary, the upper wall 322 of the grooves 35 can be formed of a dielectric material. The upper wall 322 of the trenches 32 can, for example, have a thickness substantially of between 1 nm and 600 nm.

According to a non-illustrated alternative example, the layer 20 can form the sacrificial layer of the donor sub-substrate 2. A semiconductor oxide direct bonding can be performed, for example, silicon oxide, against semiconductor, and in particular, silicon. Following their assembly the layer 11 alone will form the second layer 31 of the substrate 3. Its thickness can therefore be chosen to obtain the desired thickness L31. According to this example, it is understood that the upper wall 322 of the trenches 32 can be formed of a semiconductor material.

According to an example, the layer 20 can form the superficial layer of the donor sub-substrate 2. A semiconductor or piezoelectric against semiconductor direct bonding, and in particular silicon, can be performed, when the layer 20 is with the basis of a semiconductor or piezoelectric material. A semiconductor against semiconductor oxide direct bonding, and in particular silicon, can be performed, when the layer 20 is with the basis of a dielectric material, and in particular, of an oxide, which is sought in a context of resorting to an embrittlement zone 22 formed by ion implantation, such as in FIG. 5A. Following their assembly, the layer 20 will form the assembly 36 of the substrate 3. Its thickness can therefore be chosen to obtain the desired thickness which can be at least equal to the value described for L31.

It is noted that it is preferable to have, for the assembly, a thickness of dielectric material, and in particular of oxide, of at least 10 nm at the bonding interface to avoid the appearance of defects.

According to another example, the layer 20 can still form the superficial layer of the donor sub-substrate 2 and the support sub-substrate 1 does not comprise any superficial layer 11 (in particular, if it is not sought to have a dielectric layer on the bonding interface and in the trenches 32). In this case, the layer 20 can still be used for a semiconductor or piezoelectric against semiconductor direct bonding, and in particular silicon, when the layer 20 is with the basis of a semiconductor material (and in particular silicon) or piezoelectric material, and when the exposed surface 1a of the support sub-substrate 1 is made of semiconductor (and in particular silicon).

Thus, a substrate 3 provided with trenches is obtained, defining individual zones which can be singled out after the manufacture of the components. The substrate 3 can thus be provided to manufacture such components and have a structure such as in the example of FIG. 5B.

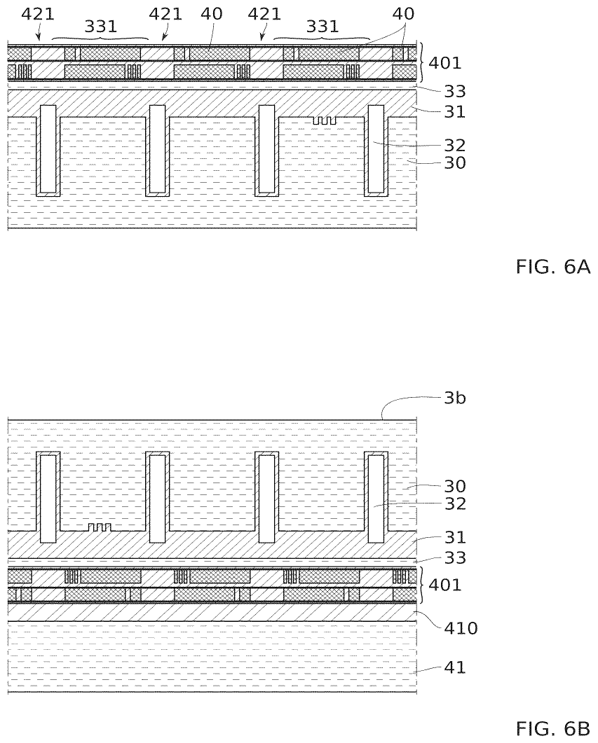

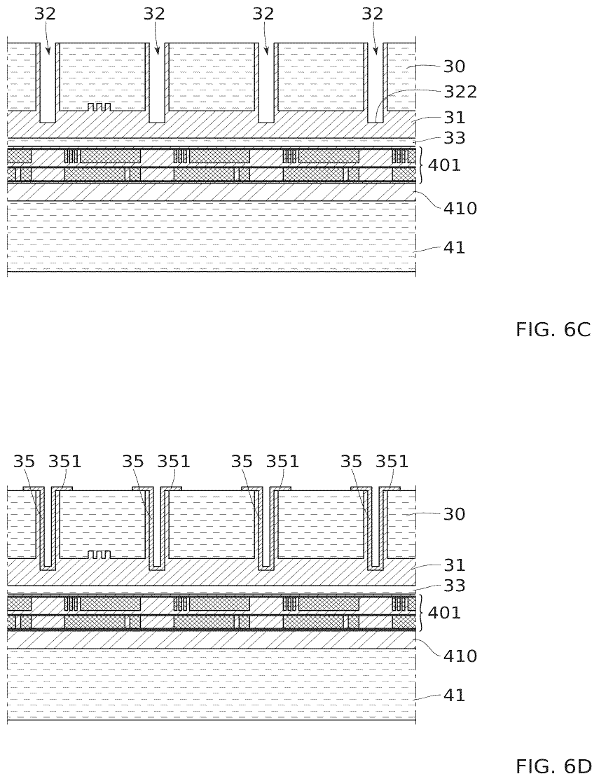

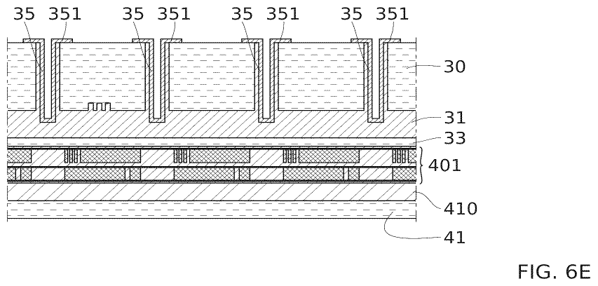

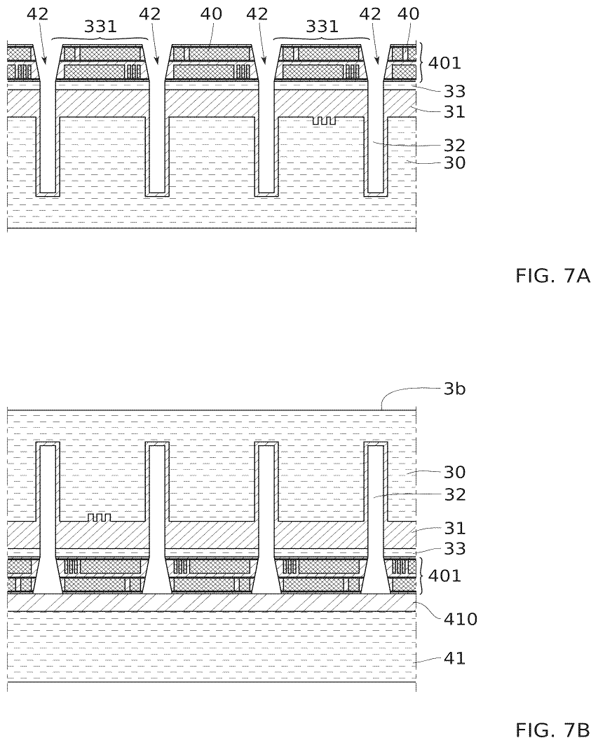

The method for manufacturing microelectronic device components 4 is now described in reference to FIGS. 6A to 7B.

In this method, the trenches 32 are used to delimit the individual zones 331. Components 40 are manufactured in these zones, preferably in a stack and this, without extending laterally beyond the individual zones 331, i.e. without overlapping the presence zone of the trenches 32.

The method can comprise a provision of the substrate 3. The method can comprise the deposition of layers of components 40 (illustrated in FIG. 6A, for example), for example, transistor, diode, memory point components. This deposition can, for example, comprise steps of the FEOL, corresponding to front-end-of-line steps.

As, for example, illustrated in FIG. 6A, the method can comprise the deposition of at least one layer portion 401 on the front surface 3a of the substrate 3. Below, it is considered, in a non-limiting manner, that several layers 401 are deposited. Alternatively, or complementarily, one or more portion(s) of these layers can be etched in the front exposed surface 3a of the substrate 3.

These components 40 can be metal, and can also, in particular, form metal interconnection lines. Typically, these metal portions 40 can be used to redistribute electrical signals. These metal portions can also be called metallisation levels. There can be several metal portions with interconnections between these portions. This deposition can, for example, comprise the steps of the BEOL.

In order to facilitate the handling of the substrate 3, the method can then comprise the mounting of a support 41 on the side of the exposed front surface 3a of the substrate 3, for example, through a bonding 410 performed on the preceding depositions, as illustrated by FIG. 6B, for example. This further makes it possible to protect the depositions performed on the front surface 3a of the substrate 3.

After the deposition of the metal portions forming the components 40 of each microelectronic device, if necessary, after the mounting of the support 41, the method comprises a tapering of the substrate 3 by the rear face 3b, so as to open the trenches 32, to achieve the configuration of FIG. 6C. This tapering can be achieved by any means in the scope of a person skilled in the art, which includes, for example, grinding and chemical or mechanical chemical polishing steps.

Optionally, this opening can also comprise one or more steps of etching at least one trench 32, in particular when the bottom wall 321 comprises a coating, and in particular, a dielectric layer.

According to an example, from the rear surface 3b of the substrate 3, the first layer 30 can be etched up to being flush, or exceeding the bottom wall 321 of the trenches 32. The bottom wall 321 of the trenches 32 is thus exposed. For that, the first layer 30 can be tapered and etched by a selective etching of the material of the first layer 30 with respect to the dielectric material of the walls 320, 321. According to an option, the etching can, for example, be a selective etching of silicon with respect to silica SiO₂ by reactive ion etching using a precursor such as SF₆. By “selective etching of a material A with respect to a material B”, this means that the etching speed of the material A is 10 times, and preferably 100 times, greater than that of the material B. The performing of a partial mechanical tapering of the substrate 3 ended by a plasma or selective chemical etching can also be considered.

The dielectric material wall can then be selectively etched with respect to the material of the first layer 30, to open into the trench 32.

When the walls of the trenches 32 are not made of dielectric material, the method can comprise the formation of a dielectric layer at at least the side wall 320 at this stage, according to the methods described above in reference to the method for manufacturing the substrate 3.

As FIG. 6D shows, it is possible, at this stage, to perform additional steps through the rear face. In particular, a metal coating 35 can be produced, for example, intended for an electromagnetic protection of the microelectronic devices 4. For example, the coating can be constituted of one or more metal layers, and in particular, a stack of a layer of, or with the basis of, titanium being used as a diffusion barrier and of a layer of, or with the basis of, copper being used as a main metal layer. It is understood that, after the separation of the devices 4, the flank of the latter is insulated without additional steps. Deposition techniques can be used to do this. The coating 35 is, at the very least, formed so as to cover the side wall 320 of the trenches 32, and typically also covers the bottom wall 321.

Optionally, the coating 35 can be extended to the surface of the substrate 3 by a portion 351 extending only over a part of the surface of the peripheral substrate 3, and in the continuity, of the coating 35 of the trenches 32.

Once the manufacturing steps occurring on the rear surface 3b of the substrate 3 have ended, the support 41 can be used as a basis for finalising the separation of the microelectronic devices 4. In this context, if this is useful, the support 41 can be reduced by thickness, as the passage from FIG. 6D to FIG. 6E illustrates. This can be a tapering according to the techniques described above for the tapering of the first layer 30 of the substrate 3.

In the configuration obtained in FIG. 6E, the microelectronic devices 4 are only longer linked to one another by thin material zones in the second layer 31 and the third layer 33 and, on the other side of the components 40, by the support 41, or a residual part of the latter, with the bonding interface 410.

Their separation can occur in a facilitated manner.

According to a first option, an etching of the bottom of the trenches is performed, i.e. of the upper wall 322, so as to pass through all of the substrate 3 around the components 40 and to join the support 41. Optionally, the latter can also be etched to single out the microelectronic devices 4. It can also be left as is to be used as a handle for the microelectronic devices 4. To this end, it can be arranged, such that the bonding layer 410 has an adhesion force of each device 4 less than an adhesion force of a subsequent and individual handling device of the devices 4, such as an appliance for gripping and positioning dies, generally called under the English term “pick-and-place” appliance.

According to another option, the support 41 is benefited from to stretch the latter in the direction of the extension plane of the bonding interface 410. The latter mechanically urges the substrate 3 and the zones where the trenches 32 are located form weakness zones, therefore concentration of stresses, at the level of which a rupture of the substrate 3 is triggered. In this context, it is advantageous to have a reduced distance between the upper wall 322 of the trenches 32 and the contact surface between the bonding layer 410 and the upper face of the components 40. Thus, the stretching forces in the plane are limited.

FIGS. 7A and 7B have an alternative case to the separation described above. Indeed, by being based on the variant of a substrate described in reference to FIG. 1B and returned to FIG. 7B, the substrate 3 has complementary trenches 42 formed in the continuity of the trenches 32, even though the microelectronic devices 4 are already insulated from one another by the front face 3a of the substrate 3 before the opening of the trenches 32 by the rear face 3b.

In particular, based on the result obtained in FIG. 6A, one or more etching steps can be carried out, making it possible to form the complementary trenches 42 from the face of the substrate 3 at the level of which the components 40 are present. The examples of etching given above can be referred to for these steps. Preferably, the complementary trenches 42 follow one same contour as that of the trenches 32.

Thanks to these complementary trenches 42, when the substrate 3 is transferred onto the support 41 as in FIG. 7B, it is understood that the carrying out of the steps corresponding to FIG. 6C (optionally, those of the steps of FIG. 6D and of FIG. 6E) makes it possible to completely individualise the devices 4 which are simply held individually on the support 41 for a subsequent individual handling.

It is reminded that the closed contours defined by the trenches 32 can have different shapes of the grid illustrated in FIG. 2, in particular, by using trenches with a curvilinear profile. Furthermore, additional trenches can be produced within one or more individual zones 331, itself having a closed contour, so as to define a hollow zone for placing components, with for example, an annular profile. The manufacture of such additional trenches can be performed at the same time as the trenches 32 and/or by implementing the same type of etching.

In view of the description above, it clearly appears that the invention proposes a substrate, its manufacturing method and a method for manufacturing a microelectronic device making it possible to facilitate the separation of microelectronic devices.

The present invention is not limited to the examples described above. Plenty of other variants of embodiments are possible, for example, by combination of features described above, without moving away from the scope of the invention. Furthermore, the features described relative to an aspect of the invention can be combined with another aspect of the invention. In particular, the substrate can have any feature resulting from its manufacturing method and vice versa, this method can comprise any step configured to obtain a feature of the substrate. The method for manufacturing a microelectronic device can implement any feature of the substrate.

In the described examples, the semiconductor material is made of silicon. It is noted that the invention can absolutely be applied to other mono-or polycrystalline semiconductors, optionally doped, and in particular, to Si, Ge, SiGe, SiC, III-V material (for example, AIN, GaN, InN, InGaAs, GaP, InP, InAs, AsGa, etc.), and II-VI material semiconductors. The dielectric material can be an oxide or a semiconductor nitride, for example, SiO₂, SIN, Al₂O₃. The piezoelectric material can, as an example, by lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a lead-magnesium and lead titanate compound (PMN-PT), zinc oxide (ZnO), aluminium nitride (AIN) or aluminium and scandium nitride (AlScN), other materials being able to naturally be considered.

1. A substrate comprising:
a first layer based upon a semiconductor material and comprising a front face and a rear face,
an assembly of at least one layer, surmounting the first layer by the front face, and comprising a plurality of individual zones for forming microelectronic components, wherein
the substrate comprises a plurality of hollow trenches extending, along a thickness dimension of the substrate at least over a portion of the first layer going up to the front face of the first layer the trenches being delimited at least by a side wall and a bottom wall buried in the first layer the trenches forming a closed contour around at least one individual zone,
the assembly comprises a second layer in contact with the front face of the first layer and which is a layer based upon a material chosen from among a dielectric material, a semiconductor material or a piezoelectric material, and
the assembly comprises a third layer surmounting the second layer and which is based upon a material chosen from among a semiconductor material or a piezoelectric material.

2. The substrate according to claim 1, comprising at least one microelectronic component in the at least one individual zone.

3. The substrate according to claim 2, comprising complementary trenches extending along the thickness dimension from an exposed face of the at least one microelectronic component up to a mouth of the trenches.

4. The substrate according to claim 1, wherein each trench extends into the first layer over at least 10% of a thickness dimension of the first layer.

5. The substrate according to claim 1, wherein at least the bottom wall and the side wall are made of dielectric material.

6. The substrate according to claim 1, wherein at least the bottom wall and the side wall comprise a layer made of a dielectric material fully covered by a metal coating.

7. The substrate according to claim 1, wherein each trench has at least a smallest transverse dimension less than 10 μm.

8. The substrate according to claim 1, wherein at least a part of the trenches has a shape ratio of a trench dimension along a thickness dimension over a smallest transverse thickness dimension, greater than or equal to 10.

9. A method for manufacturing the substrate according to claim 1, comprising:
providing a support sub-substrate comprising the first layer based upon a semiconductor material, the support sub-substrate having an exposed surface,
etching a plurality of the trenches such that the trenches extend along a thickness dimension of the substrate from the exposed surface over a portion of the first layer each trench being delimited by the side wall and the bottom wall buried in the first layer the trenches forming the closed contour around the at least one individual zone for forming microelectronic components,
providing a donor sub-substrate comprising a superficial layer having an exposed surface, and
assembling the support sub-substrate and the donor sub-substrate by their exposed surfaces so as to cover the trenches, each trench thus being delimited by the side wall, the bottom wall, and an upper wall opposite the bottom wall

10. The method according to claim 9, comprising forming at least one microelectronic component in the at least one individual zone after assembly of the support sub-substrate and of the donor sub-substrate.

11. The method according to claim 10, comprising, after forming the at least one microelectronic component, forming complementary trenches extending along the thickness dimension from an exposed face of the at least one component up to a mouth of the trenches.

12. The method according to claim 9, wherein following the etching of the plurality of trenches and before the assembly of the support sub-substrate and of the donor sub-substrate, the method comprises, for each trench a formation of a dielectric material at at least the bottom wall and the side wall.

13. The method according to claim 9, wherein the superficial layer of the donor sub-substrate is a layer based upon a material chosen from among a dielectric material, a semiconductor material or a piezoelectric material.

14. Method The method according to claim 9, wherein:
the support sub-substrate further comprises a superficial layer based upon a dielectric material, surmounting the first layer, the superficial layer of the support sub-substrate having the exposed surface and/or
the superficial layer of the donor sub-substrate is a layer based upon a dielectric material surmounting a layer based upon a material chosen from among a semiconductor material or a piezoelectric material.

15. The method according to claim 9, comprising, after assembling the support sub-substrate and the donor sub-substrate, tapering the donor sub-substrate configured to expose the superficial layer of the donor sub-substrate.

16. A method for manufacturing a microelectronic device comprising:
providing a substrate according to claim 2 having a front exposed surface and a rear exposed surface, and
tapering the first layer from the rear exposed surface up to opening the trenches.

17. Method The method according to claim 16 comprising, prior to the tapering, transferring the substrate onto a support from a face opposite the rear face.

18. The method according to claim 17 comprising, after transferring the substrate onto the support, an applying a transverse force to the thickness dimension of the substrate onto the support, so as to divide the substrate into as many microelectronic devices as closed contours formed by the trenches.

19. The method according to claim 16 comprising, after the tapering, forming a metal coating covering at least an upper wall and the side wall of the trenches.
